(19) United States
(12) Patent Application Publication
(10) Pub. No.: US 2011/0193915 A1
(43) Pub. Date: Aug. 11, 2011

(54) Piezoelectric actuator, inkjet head including the same, and method of manufacturing piezoelectric actuator

(75) Inventors: Ju Hwan Yang, Suwon (KR); Yun Sung Kang, Suwon (KR); Young Seuck Yoo, Seoul (KR); Jae Hun Kim, Seoul (KR); Jae Woo Joung, Suwon (KR)

(73) Assignee: SAMSUNG ELECTRO-MECHANICS CO., LTD., Suwon (KR)

(21) Appl. No.: 12/923,865

(22) Filed: Oct. 12, 2010

(30) Foreign Application Priority Data
Feb. 8, 2010 (KR) 10-2010-0011583

(51) Int. Cl. B41J 2/045; H01L 41/22

(52) U.S. Cl. 347/71; 29/25.35

(57) ABSTRACT

A piezoelectric actuator according to an aspect of the invention may include: upper and lower electrodes supplying a driving voltage; and a piezoelectric material formed by solidifying a piezoelectric liquid having viscosity between the upper and lower electrodes and providing a driving force to ink inside an ink chamber of an inkjet head.

### CROSS-REFERENCE TO RELATED APPLICATIONS

This application claims the priority of Korean Patent Application No. 10-2010-0011583 filed on Feb. 28, 2010, in the Korean Intellectual Property Office, the disclosure of which is incorporated herein by reference.

### BACKGROUND OF THE INVENTION

1. Field of the Invention

The present invention relates to an piezoelectric actuator, an inkjet head including the same, and a method of manufacturing a piezoelectric actuator, and more particularly, to a piezoelectric actuator realizing low-voltage driving and having high performance, an inkjet head including the same, and a method of manufacturing a piezoelectric actuator.

2. Description of the Related Art

In general, an inkjet print head is a structure for converting an electrical signal into a physical force to allow ink to be ejected in droplets through a small nozzle.

Recently, a piezoelectric inkjet head has been employed in industrial inkjet printers. For example, a piezoelectric inkjet head is used to jet ink generated by melting a metal such as gold, silver, and the like, onto a printed circuit board (PCB) to directly form a circuit pattern. A piezoelectric inkjet head is also used for industrial graphics. In addition, a piezoelectric inkjet head is used to manufacture a liquid crystal display (LCD) and an organic light emitting diode (OLED), or used for the production of solar cells, and the like.

In general, an inkjet had includes an inlet and an outlet in a cartridge through which ink is respectively introduced and ejected, a manifold storing the ink being introduced, and chambers transmitting a driving force of an actuator in order to move the ink inside the manifold to nozzles. A piezoelectric actuator, manufactured using a piezoelectric material, is mounted on the surface of the inkjet head so as to eject the ink stored in the chambers to the outside.

A piezoelectric actuator according to the related art is coupled to the inkjet head by using a screen printing method or an epoxy bonding method for bulk ceramics.

However, the above-described methods require a high thickness of the piezoelectric actuator for inkjet ejection and a high voltage in order to achieve desired inkjet ejection.

However, an increase in the thickness of the piezoelectric actuator causes a decrease in the number of nozzles per unit area. Also, a low voltage does not allow for the driving of the piezoelectric actuator, and a drop ejection frequency is limited.

Therefore, in terms of driving an inkjet head, there is a need for a method of allowing for low-voltage driving, increasing the number of nozzles per unit area, and allowing for ejection at high frequency.

### SUMMARY OF THE INVENTION

An aspect of the present invention provides a piezoelectric actuator that can increase the number of nozzles per unit area by coupling a piezoelectric actuator to an inkjet head by using an inkjet printing method, and allow for low-voltage driving, an inkjet head including the same, and a method of manufacturing a piezoelectric actuator.

According to an aspect of the present invention, there is provided a piezoelectric actuator including: upper and lower electrodes supplying a driving voltage; and a piezoelectric material formed by solidifying a piezoelectric liquid having viscosity between the upper and lower electrodes and providing a driving force to ink inside an ink chamber of an inkjet head.

The piezoelectric material may be formed using the piezoelectric liquid by inkjet printing.

The piezoelectric material may have a thickness ranging from 1 μm to 10 μm.

At least one of the upper and lower electrodes may be formed using an electrode material by inkjet printing.

The lower electrode may have a thickness ranging from 100 nm to 200 nm and may be subjected to heat treatment at a temperature between 300° C. and 400° C.

The piezoelectric actuator may further include a flexible printed circuit board connected to the upper and lower electrodes and supplying power thereto.

A wire connecting the upper electrode and the flexible printed circuit board may be formed using an electrode material by inkjet printing.

The piezoelectric actuator may further include an insulation part provided between the lower electrode and the upper electrode in order to provide electrical insulation between the upper electrode and the lower electrode.

The lower electrode may include a lower electrode terminal portion, a piezoelectric bonding portion bonded to the piezoelectric material, and a connecting portion connecting the piezoelectric bonding portion and the lower electrode terminal portion, and the insulation part is provided on a top surface of the connection portion and an outer side of the piezoelectric bonding portion.

According to another aspect of the present invention, there is provided a method of manufacturing a piezoelectric actuator, the method including: locating a lower electrode on a top surface of a passage plate of an inkjet head; forming a piezoelectric liquid having viscosity on the lower electrode by inkjet printing and solidifying the piezoelectric liquid to thereby form a piezoelectric material; and locating an upper electrode on a top surface of the piezoelectric material.

The piezoelectric liquid may be subjected to heat treatment including drying, pyrolysis and sintering to grow grains thereof, and is then solidified.

During the heat treatment, the drying may be performed at a temperature ranging from 100° C. to 200° C., the pyrolysis may be performed at a temperature ranging from 300° C. to 400° C., and the sintering may be performed at a temperature of 600° C. to 700° C.

The piezoelectric material may be formed by inkjet printing to have a thickness ranging from 1 μm to 10 μm.

At least one of the upper and lower electrodes may be formed using an electrode material by inkjet printing.

The lower electrode may have a thickness between 100 nm and 200 nm, may be subjected to heat treatment at a temperature between 300° C. and 400° C., and may then be located on a top surface of the passage plate.

The method may further include soldering a flexible printed circuit board to the upper and lower electrodes so that the flexible printed circuit board is connected to the upper and lower electrodes and supplies power thereto.

The upper electrode may include a wire connected to the flexible printed circuit board, and the wire may be formed using an electrode material by inkjet printing.

The method may further include forming an insulation part on a region of the lower electrode, where the piezoelectric material is not formed by inkjet printing, after forming the piezoelectric material.

The lower electrode may include a lower electrode terminal portion, a piezoelectric bonding portion bonded to the piezoelectric material, and a connecting portion connecting the piezoelectric bonding portion and the lower electrode terminal portion, and the insulation part may be formed on a top surface of the connecting portion and an outer side of the piezoelectric bonding portion.

According to another aspect of the present invention, there is provided an inkjet head including: a passage plate having a plurality of ink chambers; a nozzle plate having a plurality of nozzles respectively connected to the plurality of ink chambers in order to eject ink inside the ink chambers to an outside; and a piezoelectric actuator having upper and lower electrodes supplying a driving voltage and a piezoelectric material formed by solidifying a piezoelectric liquid having viscosity between the upper and lower electrodes and supplying a driving force to the ink inside an ink chamber of an inkjet head.

The piezoelectric material may be formed using the piezoelectric liquid by inkjet printing.

The piezoelectric material may have a thickness ranging from 1 μm to 10 μm.

At least one of the upper and lower electrodes may be formed using an electrode material by inkjet printing.

The lower electrode may have a thickness ranging from 100 nm to 200 nm and is subjected to heat treatment at a temperature ranging from 300° C. to 400° C.

The inkjet head may further include a flexible printed circuit board connected to the upper and lower electrodes and supplying power thereto.

A wire connecting the upper electrode and the flexible printed circuit board may be formed using an electrode material by inkjet printing.

The inkjet head may further include an insulation part provided between the lower electrode and the upper electrode for electrical insulation between the upper electrode and the lower electrode.

The lower electrode may include a lower electrode terminal portion, a piezoelectric bonding portion bonded to the piezoelectric material, and a connection portion connecting the piezoelectric bonding portion and the lower electrode terminal portion, and the insulation part is provided on a top surface of the connecting portion and an outer side of the piezoelectric bonding portion.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cut-away perspective view illustrating an inkjet head according to an exemplary embodiment of the present invention;

FIG. 2 is a schematic cross-sectional view illustrating an inkjet head according to an exemplary embodiment of the present invention;

FIG. 3 is an enlarged cross-sectional view illustrating a portion A of a piezoelectric actuator according to another exemplary embodiment of the present invention;

FIG. 4 is a schematic plan view illustrating a piezoelectric actuator according to another exemplary embodiment of the invention; and

FIGS. 5A through 5F are cross-sectional views illustrating the process flow of a method of manufacturing a piezoelectric actuator according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the same reference numerals will be used throughout to designate the same or like components.

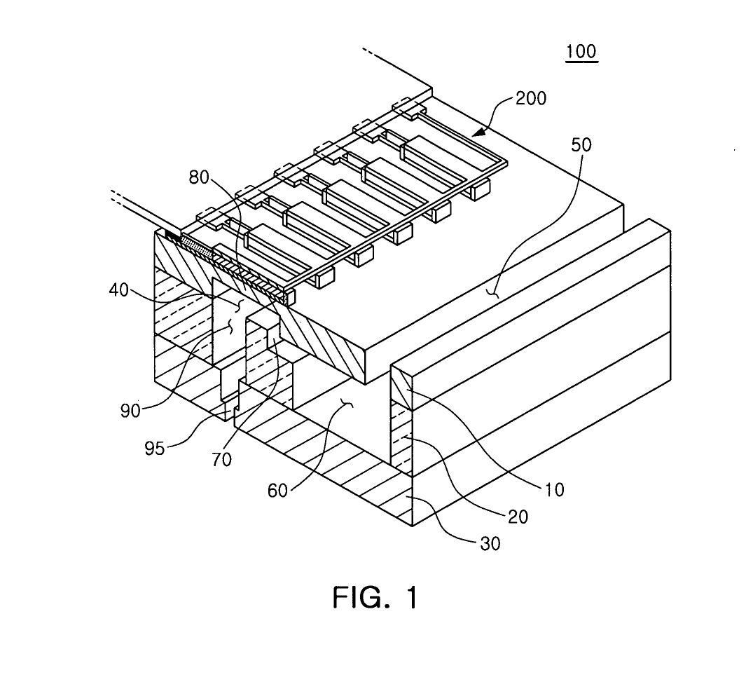

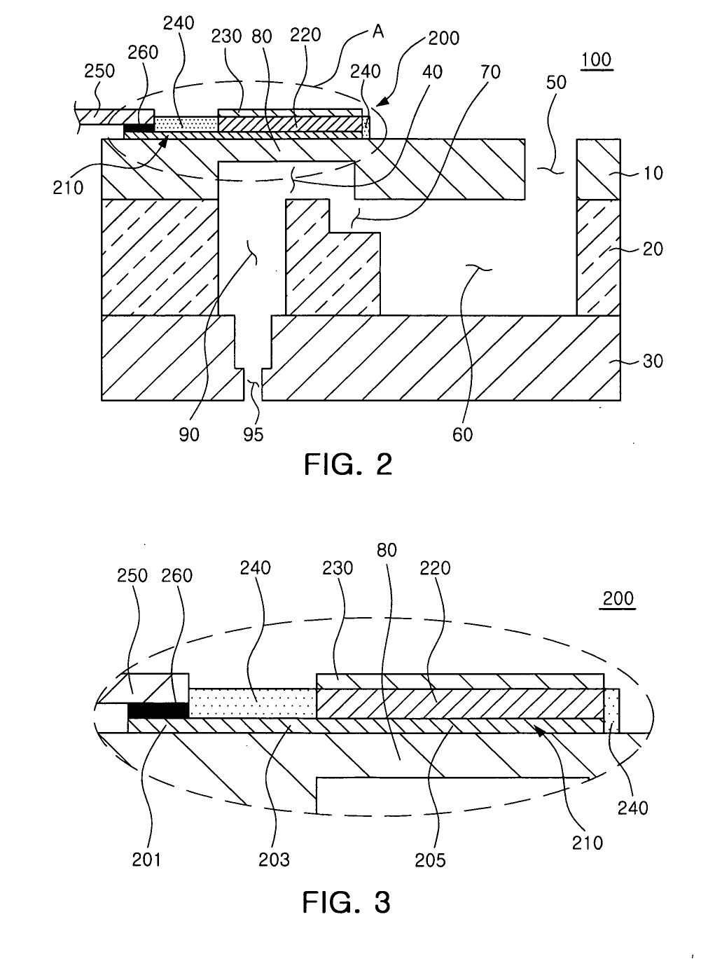

FIG. 1 a schematic cut-away perspective view illustrating an inkjet head according to an exemplary embodiment of the invention. FIG. 2 is a schematic cross-sectional view illustrating an inkjet head according to an exemplary embodiment of the invention.

Referring to FIGS. 1 and 2, an inkjet head 100 according to this embodiment may include a passage plate 10, an intermediate plate 20, a nozzle plate 30, and a piezoelectric actuator 200.

The passage plate 10 has a plurality of ink chambers 40 arranged at regular intervals and an ink inlet hole 50 formed therein. The ink inlet hole 50 is directly connected to a manifold 60, and the manifold 60 serves to supply ink to the ink chambers 40 through a restrictor 70.

Here, the manifold 60 may be formed as a single large space and be connected to the individual ink chambers 40. However, the present invention is not limited thereto, and a plurality of manifolds may be provided so that the manifolds may correspond to the respective ink chambers 40.

Furthermore, the manifold 60 may be provided by forming a recess having an internal space within the intermediate plate 20 and the nozzle plate 30.

In the same manner, even though the ink inlet hole 50 may correspond to the manifold 60, in the case that a plurality of manifolds 60 are formed, a plurality of ink inlet holes are formed so as to correspond to the respective manifolds 60.

The ink chambers 40 are located below a position in which a piezoelectric actuator 200 to be described below is mounted. Here, a portion of the passage plate 10 that forms a ceiling of the ink chambers 40 serves as a membrane 80.

Therefore, for the injection of ink, when a driving signal is applied to the piezoelectric actuator 200, the piezoelectric actuator 200 and the membrane 80 located thereunder are deformed simultaneously, thereby reducing the volume of the ink chambers 40.

The ink inside the ink chambers 40 is ejected to the outside due to an increase of pressure inside the ink chambers 40 by a damper 90 and nozzle 95.

As for the passage plate 10, in order to accurately determine the height of the ink chambers 40, an SOI (silicon on insulator) substrate in which an intermediate oxide film serving as an etching stop layer is formed may be used.

The intermediate plate 20 may include the manifold 60 extending in a longitudinal direction and a damper 90 connecting the nozzle 95 and the ink chambers 40.

The manifold 60 receives ink through the ink inlet hole 50 and supplies the ink to the ink chambers 40. The manifold 60 and the ink chambers 40 are connected to each other by the restrictor 70.

The damper 90 receives the ink being ejected from the ink chambers 40 by the piezoelectric actuator 200, and ejects the ink to the outside through the nozzle 95.

Furthermore, the damper may have a multi-stage configuration. This multi-stage configuration allows for the control of the amount of ink flowing from the ink chambers 40 and the amount of ink being transferred to the nozzle 95.

Here, the damper 90 is optional and may be removed. In this case, the inkjet head 100 may be configured by using only the passage plate 10 and the nozzle plate 30 to be described below.

The nozzle plate 30 corresponds to the individual ink chambers 40 and has the nozzle 95 so as to eject the ink, passing through the damper 90, to the outside. The nozzle plate 30 is bonded to the bottom of the intermediate plate 20.

The ink, moving through a passage formed inside the inkjet head 100, is ejected in droplets through the nozzle 95.

Here, as for the passage plate 10, the intermediate plate 20, and the nozzle plate 30, a silicon substrate being widely used in a semiconductor integrated circuit may be used. However, the passage plate 10, the intermediate plate 20, and the nozzle plate 30 are not limited to the above-described silicon substrate. Various types of materials may be used to form the above-described plates.

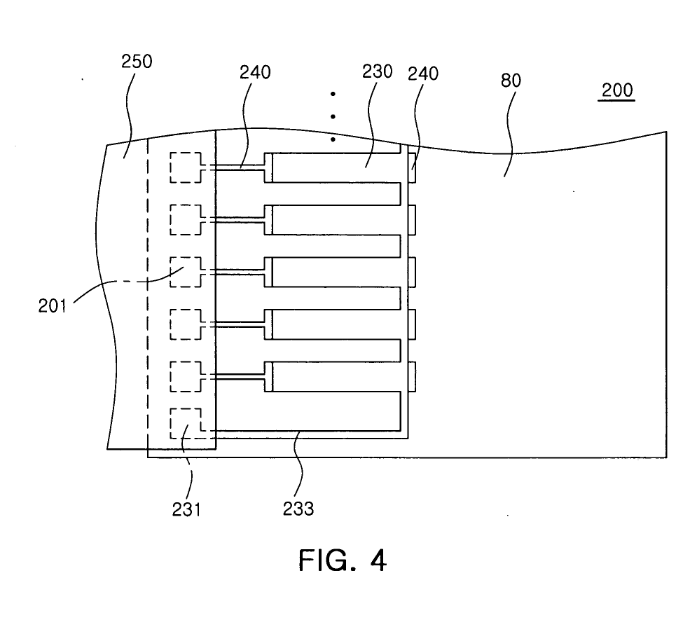

The piezoelectric actuator 200 will be described below with reference to FIGS. 3 and 4.

FIG. 3 is an enlarged cross-sectional view illustrating a portion A of a piezoelectric actuator according to another exemplary embodiment of the invention. FIG. 4 is a schematic plan view illustrating a piezoelectric actuator according to another exemplary embodiment of the invention.

With reference to FIGS. 3 and 4, a piezoelectric actuator 200 according to another exemplary embodiment of the invention may include a lower electrode 210, a piezoelectric material 220, an upper electrode 230, and an insulation part 240.

The lower electrode 210 may include a lower electrode terminal portion 201, a piezoelectric bonding portion 205, and a connecting portion 203.

The flexible printed circuit board 250 is connected to the lower electrode terminal portion 201, and the piezoelectric material 220 to be described below is connected to the piezoelectric bonding portion 205.

Furthermore, the insulation part 240 to be described below is connected to the connecting portion 203 connecting the lower electrode terminal portion 201 and the piezoelectric bonding portion 205 to each other.

The lower electrode 210 supplies a driving voltage in order to apply a driving force to the ink chambers 40. Here, the lower electrode 210 may be formed on the passage plate 10 by inkjet printing.

The lower electrode 210 may have a thickness between 100 nm and 200 nm and be subjected to heat treatment at a temperature between 300° C. and 400° C.

That is, the lower electrode 210 is formed by inkjet printing, thereby thinning the piezoelectric actuator 200.

The piezoelectric material 220 is formed by solidifying a piezoelectric liquid having viscosity between the lower electrode 210 and the upper electrode 230, thereby providing a driving force to the ink inside the ink chambers 40 of the inkjet head 100.

The piezoelectric material 220 is capable of converting electrical energy into mechanical energy, and vice versa. Here, the piezoelectric material 220 may be formed of a lead zirconate titanate (Pb(Zr,Ti)O₃:PZT) ceramic material.

Here, the piezoelectric material 220 may be formed using the piezoelectric liquid by an inkjet printing method. By using the inkjet printing method, the piezoelectric material 220 may have a thickness ranging from 1 μm to 10 μm.

As the thickness of the piezoelectric material 220 is decreased, like the lower electrode 210, it is possible to thin the piezoelectric actuator 200 to thereby increase the number of nozzles 95 per unit area, allowing for low-voltage driving and high-frequency ejection.

When voltage is applied to the piezoelectric material 220, a driving force is vertically transmitted due to the vertical deformation of the membrane 80. A driving force being generated at this time causes the ink inside the ink chambers 40 to be ejected to the outside through the nozzle 95.

The nozzle 95 extends towards side surfaces of the nozzle plate 30 in a widthwise direction, so that the ink may be ejected in a direction perpendicular to a direction in which the driving force is transferred inside the ink chambers 40.

Like the lower electrode 210, the upper electrode 230 may apply a driving voltage in order to supply a driving force to the ink chambers 40, and be formed on the top surface of the piezoelectric material 220 by inkjet printing.

The upper electrode 230 may include an upper electrode terminal portion 231 connected to the flexible printed circuit board 250, and wires 233 used to connect the upper electrode terminal portion 231 and the flexible printed circuit board 250 to each other may be formed using an electrode material by inkjet printing.

The upper electrode 230 may be negatively (−) charged by the flexible printed circuit board 250, while the lower electrode 210 may be positively (+) charged by the flexible printed circuit board 250, so that the piezoelectric material 220 may provide a driving force to the ink chambers 40.

The insulation part 240 may be formed between the lower electrode 210 and the upper electrode 230 in order to insulate the upper electrode 230 and the lower electrode 210 from each other, and prevent a short circuit between the upper electrode 230 and the lower electrode 210.

The insulation part 240 may be formed on the top surface of the connecting portion 203 of the lower electrode 210 and the outside of the piezoelectric bonding portion 205. However, the insulation part 240 is not necessarily an essential component of the piezoelectric actuator 200.

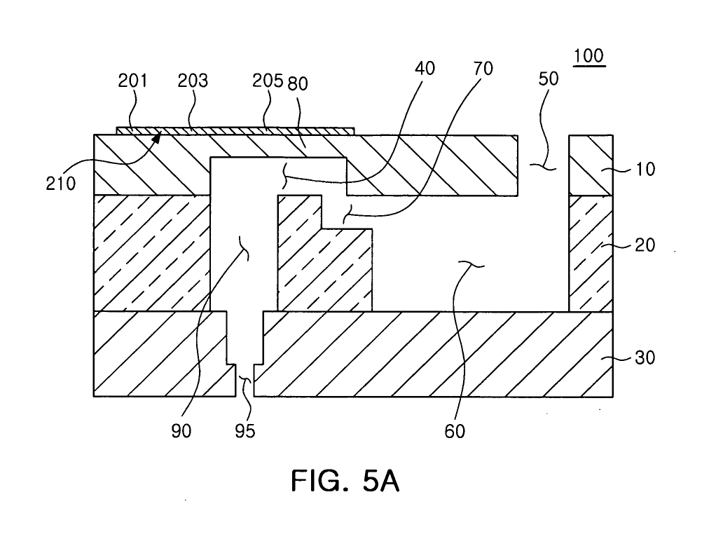

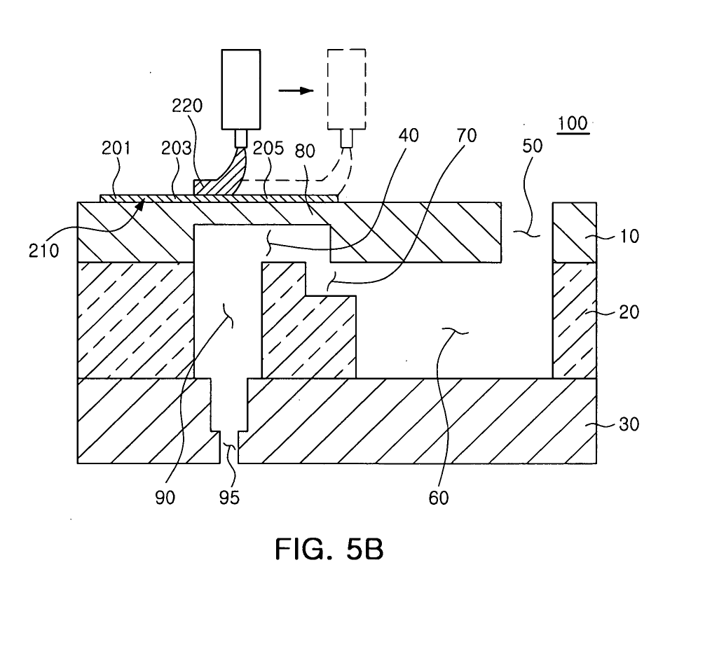

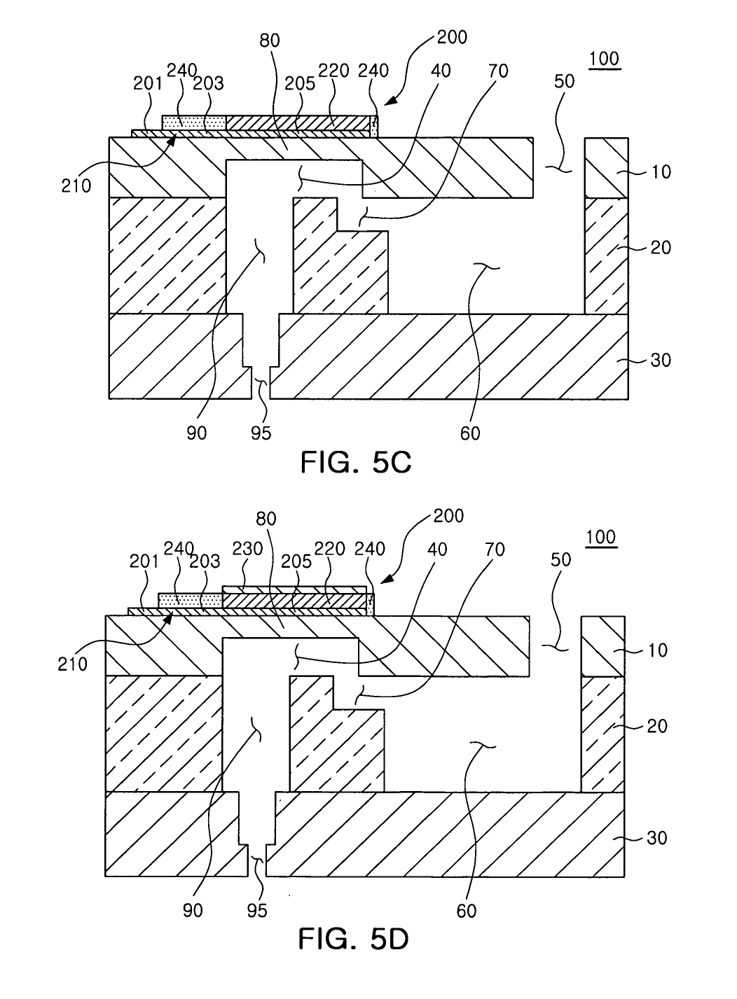

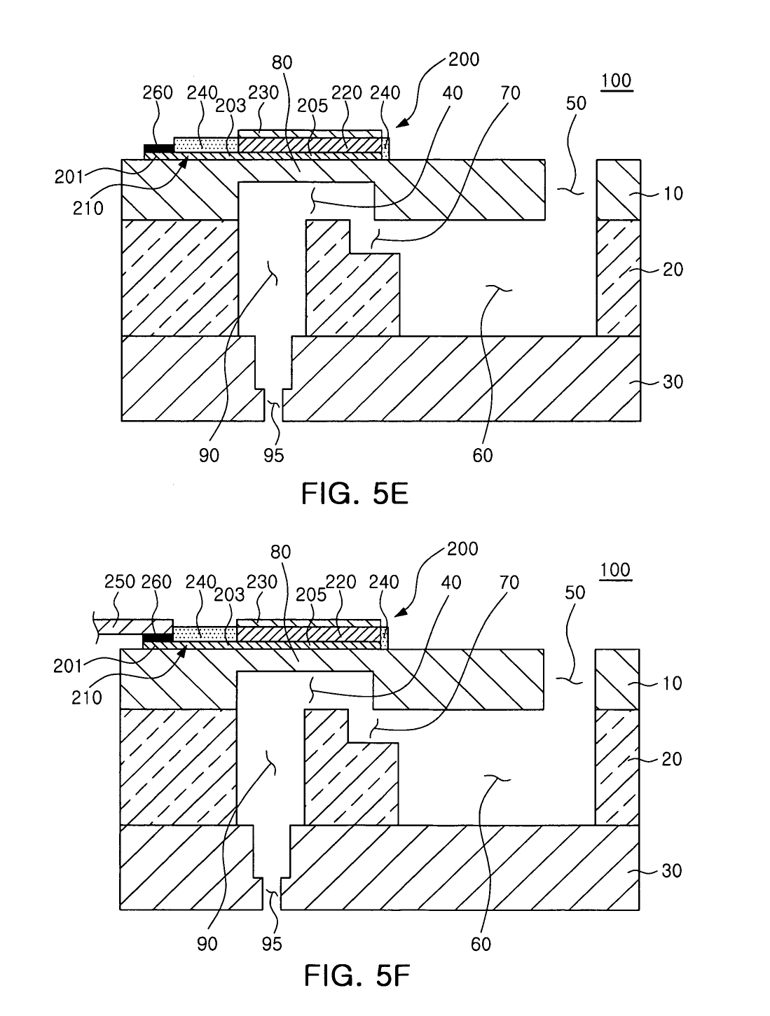

FIGS. 5A through 5F are cross-sectional views illustrating the process flow of a method of manufacturing a piezoelectric actuator according to another exemplary embodiment of the invention.

Referring to FIG. 5A, the lower electrode 210 may be located on the top surface of the passage plate 10. Here, the lower electrode 210 may be formed of Pt. However, the present invention is not limited thereto.

Furthermore, the lower electrode 210 may be formed using an electrode material by inkjet printing. The lower electrode 210 may have a thickness ranging from 100 nm to 200 nm and be subjected to heat treatment at a temperature ranging from 300° C. to 400° C. so that the lower electrode 210 is printed on the top surface of the passage plate 10.

Referring to FIG. 5B, the piezoelectric material 220, formed by solidifying a piezoelectric liquid having viscosity, is fixed to a predetermined area of the lower electrode 210 so as to provide a driving force to the ink inside the ink chambers 40.

The predetermined area of the lower electrode 210 may be the piezoelectric bonding portion 205 of the lower electrode 210, and the piezoelectric material 220 may be formed using the piezoelectric liquid by inkjet printing.

Furthermore, the piezoelectric material 220 may be formed by inkjet printing so that the piezoelectric material 220 has a thickness ranging from 1 μm to 10 μm. Later, the piezoelectric material 220 may be subjected to heat treatment including drying, pyrolysis, and sintering to thereby grow grain thereof.

During the above-described heat treatment, drying may be performed at a temperature ranging from 100 to 200° C., pyrolysis may be performed at a temperature ranging from 300 to 400° C., and sintering may be performed at a temperature of 600 to 700° C.

Referring to FIG. 5C, after the grain growth of the piezoelectric material 220 is completed, the insulation part 240 may be formed on a portion of the lower electrode 210, where the piezoelectric material 220 is not printed.

The insulation part 240 may be formed by inkjet printing on the top surface of the connecting portion 203 of the lower electrode 210 and the outside of the piezoelectric bonding portion 205. Since the insulation part 240 merely prevents a short-circuit between the upper electrode 230 and the lower electrode 210, the insulation part 240 is not necessarily an essential component of the piezoelectric actuator 200.

Referring to FIG. 5D, the upper electrode 230 may be located on the top surface of the piezoelectric material 220.

The upper electrode 230 may be formed using an electrode material by inkjet printing and supply a driving voltage so as to provide a driving force to the ink chambers 40.

The upper electrode 230 may be formed using Pt, Ag, Au or the like by inkjet printing. However, the present invention is not limited thereto. The material of the upper electrode 230 may be modified by a person skilled in the art.

Referring to FIGS. 5E and 5F, after the upper electrode 230 is disposed, the flexible printed circuit 250, connected to the upper electrode 230 and the lower electrode 210 to thereby supply power thereto, may be soldered to the upper electrode 230 and the lower electrode 210 by using solder balls 260.

As for the flexible printed circuit board 250, the wires 233, used to connect the upper electrode 230 and the flexible printed circuit board 250, may be formed using an electrode material by inkjet printing. The solder balls 260 are applied to the upper electrode terminal portion 231 of the upper electrode 230 and the lower electrode terminal portion 201 of the lower electrode 210, and the flexible printed circuit board 250 may then be bonded.

Here, the upper electrode 230 may be negatively (−) charged by the flexible printed circuit board 250, while the lower electrode 210 may be positively (+) charged by the flexible printed circuit board 250, so that the piezoelectric material 220 may provide a driving force to the ink chambers 40.

Through the above-described embodiments, a thin-film piezoelectric actuator is manufactured by inkjet printing, thereby increasing the number of nozzles per unit area, realizing low-voltage driving and increasing a drop ejection frequency.

Furthermore, since inkjet printing is used, an unnecessary lower electrode is removed to thereby prevent leakage current, and it is possible to design a driver package by various printing patterns.

As set forth above, according to exemplary embodiments of the invention, according to a piezoelectric actuator, an inkjet head including the same, and a method of manufacturing a piezoelectric actuator, a thin-film piezoelectric actuator can be manufactured by inkjet printing to thereby realize low-voltage driving and increase the number of nozzles per unit area.

While the present invention has been shown and described in connection with the exemplary embodiments, it will be apparent to those skilled in the art that modifications and variations can be made without departing from the spirit and scope of the invention as defined by the appended claims.

What is claimed is:

1. A piezoelectric actuator comprising:
upper and lower electrodes supplying a driving voltage; and
a piezoelectric material formed by solidifying a piezoelectric liquid having viscosity between the upper and lower electrodes and providing a driving force to ink inside an ink chamber of an inkjet head.

2. The piezoelectric actuator of claim 1, wherein the piezoelectric material is formed using the piezoelectric liquid by inkjet printing.

3. The piezoelectric actuator of claim 1, wherein the piezoelectric material has a thickness ranging from 1 μm to 10 μm.

4. The piezoelectric actuator of claim 1, wherein at least one of the upper and lower electrodes is formed using an electrode material by inkjet printing.

5. The piezoelectric actuator of claim 1, wherein the lower electrode has a thickness ranging from 100 nm to 200 nm and is subjected to heat treatment at a temperature between 300° C. and 400° C.

6. The piezoelectric actuator of claim 1, further comprising a flexible printed circuit board connected to the upper and lower electrodes and supplying power thereto.

7. The piezoelectric actuator of claim 6, wherein a wire connecting the upper electrode and the flexible printed circuit board is formed using an electrode material by inkjet printing.

8. The piezoelectric actuator of claim 1, further comprising an insulation part provided between the lower electrode and the upper electrode in order to provide electrical insulation between the upper electrode and the lower electrode.

9. The piezoelectric actuator of claim 8, wherein the lower electrode comprises a lower electrode terminal portion, a piezoelectric bonding portion bonded to the piezoelectric material, and a connecting portion connecting the piezoelectric bonding portion and the lower electrode terminal portion, and
the insulation part is provided on a top surface of the connection portion and an outer side of the piezoelectric bonding portion.

10. A method of manufacturing a piezoelectric actuator, the method comprising:
locating a lower electrode on a top surface of a passage plate of an inkjet head;
forming a piezoelectric liquid having viscosity on the lower electrode by inkjet printing and solidifying the piezoelectric liquid to thereby form a piezoelectric material; and
locating an upper electrode on a top surface of the piezoelectric material.

11. The method of claim 10, wherein the piezoelectric liquid is subjected to heat treatment including drying, pyrolysis and sintering to grow grains thereof, and is then solidified.

12. The method of claim 11, wherein during the heat treatment, the drying is performed at a temperature ranging from 100° C. to 200° C., the pyrolysis is performed at a temperature ranging from 300° C. to 400° C., and the sintering is performed at a temperature of 600° C. to 700° C.

13. The method of claim 10, wherein the piezoelectric material is formed by inkjet printing to have a thickness ranging from 1 μm to 10 μm.

14. The method of claim 10, wherein at least one of the upper and lower electrodes is formed using an electrode material by inkjet printing.

15. The method of claim 10, wherein the lower electrode has a thickness between 100 nm and 200 nm, is subjected to heat treatment at a temperature between 300° C. and 400° C., and is then located on a top surface of the passage plate.

16. The method of claim 10, further comprising soldering a flexible printed circuit board to the upper and lower electrodes so that the flexible printed circuit board is connected to the upper and lower electrodes and supplies power thereto.

17. The method of claim 16, wherein the upper electrode comprises a wire connected to the flexible printed circuit board, and the wire is formed using an electrode material by inkjet printing.

18. The method of claim 10, further comprising forming an insulation part on a region of the lower electrode, where the piezoelectric material is not formed by inkjet printing, after forming the piezoelectric material.

19. The method of claim 18, wherein the lower electrode comprises a lower electrode terminal portion, a piezoelectric bonding portion bonded to the piezoelectric material, and a connecting portion connecting the piezoelectric bonding portion and the lower electrode terminal portion, and
the insulation part is formed on a top surface of the connecting portion and an outer side of the piezoelectric bonding portion.

20. An inkjet head comprising:
a passage plate having a plurality of ink chambers;
a nozzle plate having a plurality of nozzles respectively connected to the plurality of ink chambers in order to eject ink inside the ink chambers to an outside; and
a piezoelectric actuator having upper and lower electrodes supplying a driving voltage and a piezoelectric material formed by solidifying a piezoelectric liquid having viscosity between the upper and lower electrodes, the piezoelectric actuator supplying a driving force to the ink inside an ink chamber of an inkjet head.

21. The inkjet head of claim 20, wherein the piezoelectric material is formed using the piezoelectric liquid by inkjet printing.

22. The inkjet head of claim 20, wherein the piezoelectric material has a thickness ranging from 1 μm to 10 μm.

23. The inkjet head of claim 20, wherein at least one of the upper and lower electrodes is formed using an electrode material by inkjet printing.

24. The inkjet head of claim 20, wherein the lower electrode has a thickness ranging from 100 nm to 200 nm and is subjected to heat treatment at a temperature ranging from 300° C. to 400° C.

25. The inkjet head of claim 20, further comprising a flexible printed circuit board connected to the upper and lower electrodes and supplying power thereto.

26. The inkjet head of claim 25, wherein a wire connecting the upper electrode and the flexible printed circuit board is formed using an electrode material by inkjet printing.

27. The inkjet head of claim 20, further comprising an insulation part provided between the lower electrode and the upper electrode for electrical insulation between the upper electrode and the lower electrode.

28. The inkjet head of claim 27, wherein the lower electrode comprises a lower electrode terminal portion, a piezoelectric bonding portion bonded to the piezoelectric material, and a connection portion connecting the piezoelectric bonding portion and the lower electrode terminal portion, and
the insulation part is provided on a top surface of the connecting portion and an outer side of the piezoelectric bonding portion.
